(19) United States
(12) Patent Application Publication
(10) Pub. No.: US 2009/0129026 A1
(43) Pub. Date: May 21, 2009

(54) Heat sink for semiconductor device and semiconductor module assembly including the heat sink

(75) Inventors: Joong-hyun Baek, Suwon-si (KR); Hee-jin Lee, Seongnam-si (KR); Sun-won Kang, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/292,244

(22) Filed: Nov. 14, 2008

(30) Foreign Application Priority Data
Nov. 19, 2007 (KR) 10-2007-0118122

(51) Int. Cl. H05K 7/20

(52) U.S. Cl. 361/710; 361/715

(57) ABSTRACT

Provided are a heat sink and a heat sink semiconductor module assembly which may include an improved, cooling function. Each of the heat sinks may include a flat heat sink base having a first surface attached to semiconductor devices and a second surface externally exposed; first fins provided on a portion of the second surface of the heat sink base to which no clip is coupled; and second fins provided on portions of the second surface of the heat sink base to which a clip may be coupled. The semiconductor module assembly may secure the heat sinks to both surfaces of a semiconductor module using the clip. Accordingly, air may flow smoothly through the second fins on the portions to which the clip may be coupled, thereby improving the cooling function of the heat sinks.

### PRIORITY STATEMENT

This application claims priority under 35 U.S.C. § 119 to Korean Patent Application No. 10-2007-0118122, filed on Nov. 19, 2007, in the Korean Intellectual Property Office, the entire contents of which are herein incorporated by reference.

### BACKGROUND

1. Field

Example embodiments relates to a heat sink and a semiconductor module assembly including a heat sink. Other example embodiments relate to heat sinks having fins formed on exposed surfaces thereof and/or being secured to each other using a clip. Other example embodiments relate to a semiconductor module assembly including the heat sinks.

2. Description of the Related Art

An electronic system including a semiconductor module, like a dynamic random access memory (DRAM) module, uses a high end server having an improved cooling system or a low end server having an undesirable cooling system. When the low end server, which is relatively inexpensive, is mounted in a system so that air flows into the system at a flow rate of less than 1 m/s and a temperature of higher than 50° C., and a memory module is inclined at an angle of 25 degrees, a heat spreader or a heat sink having fins may be mounted on the memory module.

Accordingly, attempts have been made to secure a heat sink to a memory module using a clip during the manufacture of the memory module in order to efficiently dissipate heat generated when a plurality of semiconductor devices operate at high speed. Methods of manufacturing a heat sink and attaching the same using a clip are disclosed in conventional art.

### SUMMARY

Example embodiments may provide a heat sink for semiconductor devices, the heat sink including a clip in order to reduce or prevent a decrease in dissipation efficiency. Example embodiments may also provide a semiconductor module assembly including the heat sink. Example embodiments may include a heat sink including a flat heat sink base having a first surface attached to semiconductor devices and a second surface exposed externally, first fins on a portion of the second surface of the heat sink base to which no clip is coupled, and second fins on portions of the second surface of the heat sink base to which a clip is coupled.

The portions of the second surface of the heat sink base to which the clip is coupled may include a portion to which the clip may be movably coupled and on which second fins having a first height may be formed, and a portion to which the clip may be fixedly coupled and on which second fins having a second height may be formed. The first height of the second fins may be greater than the second height of the second fins. The first fins on the second surface of the heat sink base may have a height greater than those of the second fins.

The first surface of the heat sink base may have a stepped structure conforming to the semiconductor devices having different heights and contacting the first surface of the heat sink base. A U-shaped groove may be formed or provided along an edge of the first surface of the heat sink base. The first fins and the second fins may have different shapes and pitches from each other. The first fins may have a first height and the second fins may have a second height. The first fins and the second fins may have different shapes and pitches from each other. The heat sink base may further comprise support bars that are connected to the flat heat sink base and are bent, for example, at about 90 degrees.

Example embodiments may include a semiconductor module assembly including a semiconductor module, on both surfaces of which semiconductor devices may be mounted, and at least two heat sinks with one heat sink being an upper heat sink attached to the semiconductor devices mounted on one surface of the semiconductor module, and the other heat sink being a lower heat sink may be attached to the semiconductor device mounted on the other surface of the semiconductor module.

The upper and lower heat sinks may further comprise support bars that are connected to the heat sink bases and are bent, for example, at about 90 degrees, wherein the support bars of the upper and lower heat sinks alternately engage with each other. The clip may have a U-shaped structure whose upper end may be wider than a lower end that is bent outward. The clip may secure the semiconductor module, the upper heat sink, and the lower heat sink in a direction in which the support bars of the upper and lower heat sinks engage with each other. Thermal interface materials (TIMs) may be provided between the semiconductor devices of the semiconductor module and the first surfaces of the upper and lower heat sinks.

Example embodiments may include a semiconductor module assembly including a recess area that may be on a portion of the surface of the heat sink base to which the clip may be fixedly coupled. The clip may have a U-shaped structure whose upper end is wider than a lower end that is linear. A groove may be formed in a position of the recess area of each of the upper and lower heat sinks where the lower end of the clip is provided.

Example embodiments may include a method of assembling a heat sink including assembling a flat heat sink base having a first surface attached to semiconductor devices and a second surface externally exposed, forming first fins on a portion of the second surface of the heat sink base to which no clip is coupled, and forming second fins on portions of the second surface of the heat sink base to which a clip is coupled. The portions of the second surface of the heat sink base to which the clip is coupled may include a portion to which the clip may be movably coupled and on which second fins having a first height may be formed, and a portion to which the clip may be fixedly coupled and on which seconds fins having a second height may be formed.

Example embodiments may include a method for assembling a semiconductor module including providing a semiconductor module with semiconductor devices mounted on both surfaces of the semiconductor module, and forming at least two heats sinks with one being an upper heat sink that is attached to the semiconductor devices on one surface of the semiconductor module, and the other being a lower heat sink that is attached to the semiconductor devices mounted on the other surface of the semiconductor module.

A recess area may be on a portion of the surface of the heat sink base to which the clip is fixedly coupled. A groove may be formed in a position of the recess area on each of the upper and lower heat sinks where the lower end of the clip is provided.

### BRIEF DESCRIPTION OF THE DRAWINGS

Example embodiments will be more clearly understood from the following detailed description taken in conjunction with the accompanying drawings. FIGS. 1-16 represent non-limiting, example embodiments as described herein.

FIG. 1 is a plan view of a semiconductor module according to example embodiments;

FIG. 2 shows a plan view and a side view of a heat sink for semiconductor devices according to example embodiments;

FIG. 3 shows cross-sectional views taken along lines A-A′ and B-B′ of FIG. 2;

FIG. 4 is a bottom view of the heat sink of FIG. 2;

FIGS. 5 and 6 are a perspective view and a side view of a clip according to example embodiments, respectively;

FIG. 7 is a side view of support bars of the heat sink of FIG. 2 according to example embodiments;

FIG. 8 is a cross-sectional view of a semiconductor module assembly including the heat sink of FIG. 2 according to example embodiments;

FIG. 9 is a plan view illustrating a modification of the heat sink of FIG. 2;

FIG. 10 is a plan view illustrating another modification of the heat sink of FIG. 2;

FIG. 11 is a plan view of a heat sink according to example embodiments;

FIG. 12 is a cross-sectional view taken along line B-B′ of FIG. 11;

FIG. 13 is a cross-sectional view taken along line A-A′ of FIG. 11;

FIG. 14 is a side view of a clip for securing the heat sink of FIG. 11 to a semiconductor module according to example embodiments;

FIG. 15 is a cross-sectional view illustrating a groove formed in a recess area of the heat sink of FIG. 11; and

FIG. 16 is a cross-sectional view of a semiconductor module assembly including the heat sink of FIG. 11 according to example embodiments.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to example embodiments set forth herein; rather example embodiments are provided so that this disclosure will be thorough and complete, and will fully convey the concept of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, like “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions, illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belongs. It will be further understood that terms, like those defined in commonly used dictionaries, should be interpreted as having a meaning that is consistent with their meaning in the context of the relevant art and will not be interpreted in an idealized or overly formal sense unless expressly so defined herein.

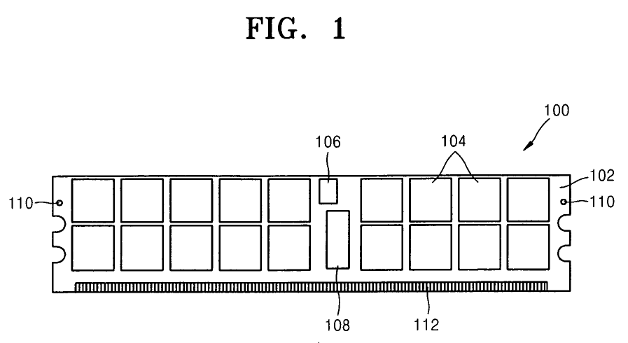

FIG. 1 is a plan view of a semiconductor module 100 according to example embodiments. Referring to FIG. 1, the semiconductor module 100, for example, a registered dual inline memory module (RDIMM) having a dynamic random access memory (DRAM) function, may include a printed circuit board (PCB) 102, a semiconductor package 106 having a register function and a semiconductor package 108 having a phase locked loop (PLL) function. DRAM semiconductor packages 104 may be mounted on the PCB 102 and the semiconductor packages 106 and 108 may be mounted in a central portion of the PCB 102. Although the semiconductor packages 104, 106, and 108 may be ball grid array (BGA) packages in FIG. 1, example embodiments are not limited thereto. Also, although the semiconductor packages 104, 106, and 108 may have memory functions, example embodiments are not limited thereto.

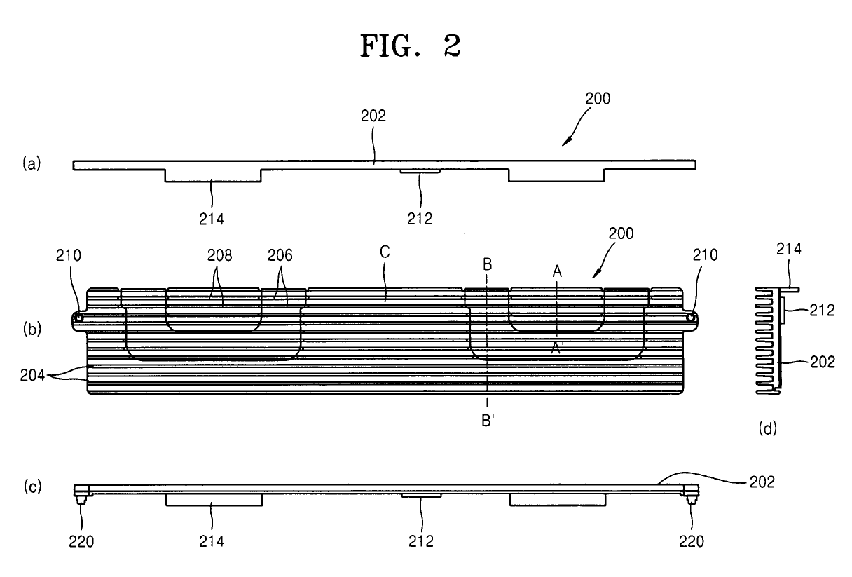

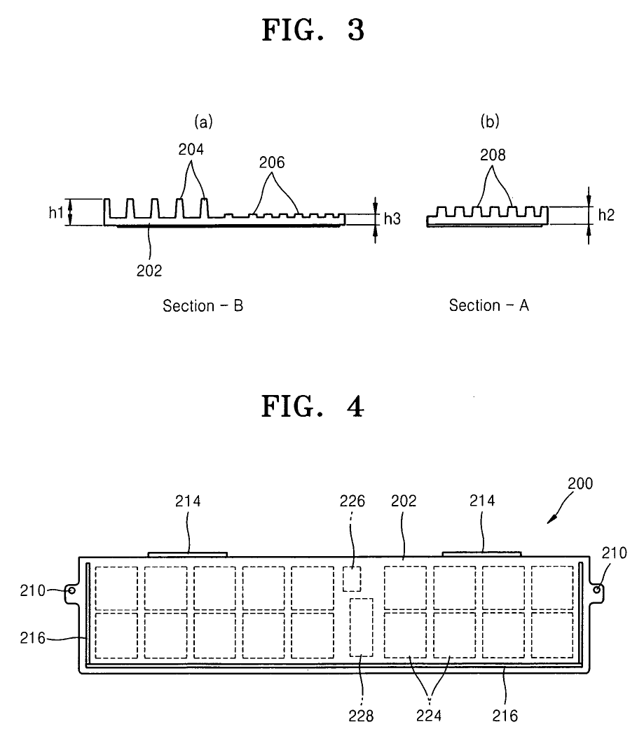

Substrate fixing pin insertion holes 110 may be formed or provided in both sides of the PCB 102. A connection terminal 112 may be formed on a side or edge, for example, a lower end of the PCB 102, such that the PCB 102 may be electrically connected to another PCB through a socket formed in a motherboard. FIG. 2 shows a plan view and a side view of a heat sink 200 for a semiconductor device according to example embodiments. FIG. 3 shows cross-sectional views taken along lines A-A′ and B-B′ of FIG. 2.

FIG. 2B is a plan view of a surface of the heat sink 200 which may be externally exposed, and FIGS. 2A, 2C, and 2D are side views of the heat sink 200. FIG. 3A shows a cross-sectional view taken along line B-B′ of FIG. 2, and FIG. 3B shows a cross-sectional view taken along line A-A′ of FIG. 2.

The heat sink 200 may include a flat heat sink base 202 having a first surface attached to a semiconductor device and a second surface externally exposed. The heat sink base 202 may be formed of a metal e.g., aluminium or copper. The heat sink base 202 may be coated with a black paint to improve a radiation heat transfer effect.

The second surface of the heat sink base 202, which may be externally exposed, may include a portion C to which a clip may not be coupled on which first fins 204 may be formed. The second surface of the heat sink base 202 may also include portions A and B to which a clip may be coupled on which second fins 206 and 208 may be formed. The clip may be movably coupled to the portion A and may be fixedly coupled to the portion B. The second fins 208 may have a first height h2 (see FIG. 3B) that may be formed on the portion A to which the clip may be movably coupled, and the second fins 206 may have a second height h3 (see FIG. 3A) that may be formed on the portion B to which the clip may be fixedly coupled. The second fins 206 and 208 may be formed on the portions B and A to form spaces 500 (see FIG. 8) through which air can continuously flow without being interrupted by the clip when the clip is coupled to the heat sink base 202, which may improve the thermal reliability of the semiconductor module 100.

The height h3 of the first fins 204, which may be formed on the portion C to which a clip may not be coupled, may be smaller than the height h2. The first height h2 of the second fins 208 may be formed on the portion A to which the clip may be movably coupled, and the second height h3 of the second fins 206 may be formed on the portion B to which the clip may be fixedly coupled.

Two fixing pin insertion holes 210 may be formed in both sides of the heat sink base 202 of FIG. 2. When two heat sinks 200 (200A and 200B) are secured to both surfaces of the semiconductor module 100 of FIG. 1, screws 220 may be screwed into the two fixing pin insertion holes 210 and into the substrate fixing pin insertion holes 110 of the semiconductor module 100. A plurality of support bars 214, which may be connected to the heat sink base 202 and may be bent, for example, at about 90 degrees, may be provided on an end of the heat sink base 202.

The first surface of the heat sink base 202, which contacts the semiconductor module 100, may not be flat, but may have a stepped structure 212 conforming to the semiconductor packages 104, 106, and 108 of the semiconductor module 100 (see FIG. 1) which may have different heights. Accordingly, the stepped structure 212 may vary according to the sizes or heights of the semiconductor packages 104, 106, and 108 mounted on the PCB 102 of the semiconductor module 100.

FIG. 4 shows a bottom view of the heat sink 200 of FIG. 2. Referring to FIG. 4, the first surface of the heat sink base 202 of the heat sink 200, which may be a bottom surface, may have the stepped structure 212 as shown in FIG. 2. A U-shaped groove 216 may be formed along an edge of the first surface that contacts the semiconductor module 100. The U-shaped groove 216 may prevent or reduce a thermal interface material (TIM) that contacts the semiconductor module 100 from flowing down at high temperature.

Reference numerals 224, 226, and 228 denote portions contacting the semiconductor package 104 which may include the memory function, the semiconductor package 106 which may include the register function, and the semiconductor package 108 which may include the PLL function. The portion 226 contacting the semiconductor package 106 which may include the register function may protrude in order to compensate for a relatively low height of the semiconductor package 106. Reference numeral 214 may denote support bars, and reference numeral 210 may denote fixing pin insertion holes.

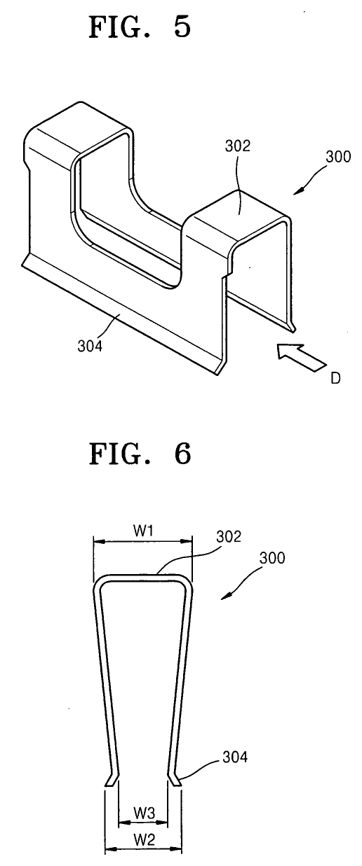

FIGS. 5 and 6 show a perspective view and a side view of a clip 300, respectively, according to example embodiments. Referring to FIGS. 5 and 6, the clip 300 may serve to attach two heat sinks 200A and 200B (see FIG. 2) to both surfaces of the semiconductor module 100 (see FIG. 1). The clip 300 may include a U-shaped structure whose upper end 302 may be closed. The clip 300 may further have a width W1 greater than widths W2 and W3 of a lower end 304. The lower end 304 may be bent outward in order to increase the holding force of the clip 300.

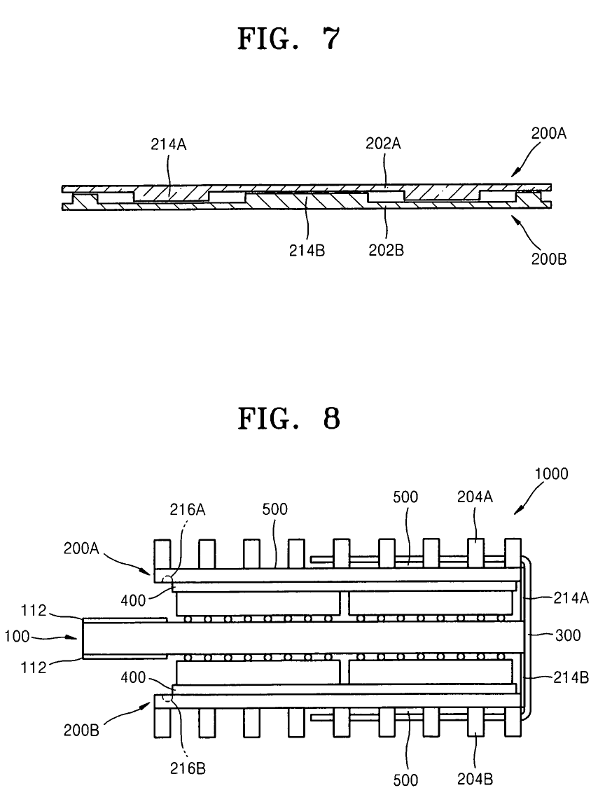

FIG. 7 is a side view of support bars 214A and 214B of the heat sinks 200A and 200B of FIG. 2. Referring to FIG. 7, the two heat sinks 200A and 200B may be coupled to each other by the support bars 214A and 214B. The support bars 214A and 214B may be connected to heat sink bases 202A and 202B. The support bars 214A and 214B each may be formed of a metal and may be bent, for example, at about 90 degrees. The support bars 214A and 214B may alternately engage with each other in order to protect the semiconductor module 100 interposed between the upper heat sink 200A and the lower heat sink 200B from an external impact.

FIG. 8 is a cross-sectional view of a semiconductor module assembly 1000 including the heat sinks 200A and 200B of FIG. 2. Referring to FIG. 8, the semiconductor module assembly 1000 may include a semiconductor module 100 on both surfaces of which semiconductor devices may be mounted. An upper heat sink 200A may be attached to the semiconductor devices mounted on one surface of the semiconductor module 100, and may have first fins 204A which may be formed on a portion of a second surface of a heat sink base to which a clip may not be coupled. Second fins 206A and 208B may be on portions of the second surface of the heat sink base to which a clip 300 may be coupled. A lower heat sink 200B may be attached to the semiconductor devices mounted on the other surface of the semiconductor module 100, and may have first fins 204B which may be formed on a portion of a second surface of a heat sink base to which no clip may be coupled. Second fins 206B and 208B may be on portions of the second surface of the heat sink base to which the clip 300 may be coupled. The clip 300 may secure the semiconductor module 100, the upper heat sink 200A, and the lower heat sink 200B.

TIMs 400 may be provided between the semiconductor devices mounted on the semiconductor module 100 and first surfaces, which may be inner surfaces, of the heat sink bases of the upper heat sink 200A and the lower heat sink 200B. The clip 300 may have a structure wherein an upper end is wider than a lower end that is bent outward. The clip 300 may secure the semiconductor module 100, the upper heat sink 200A, and the lower heat sink 200B in a direction in which support bars 214A and 214B of the upper heat sink 200A and the lower heat sink 200B engage with each other.

U-shaped grooves 216A and 216B may be formed along edges of the first surfaces of the upper heat sink 200A and the lower heat sink 200B. When the semiconductor module assembly including the upper heat sink 200A and the lower heat sink 200B is exposed to increased temperatures for a relatively long time and the TIMs 400 are phase change materials, despite the TIMs 400 flowing down at high temperature, the U-shaped grooves 216A and 216B may prevent or reduce the TIMs 400 from leaking externally.

Because the support bars 214A and 214B and the clip 300 may be formed on one side of the semiconductor module assembly 1000 including the upper heat sink 200A, the lower heat sink 200B, and connection terminals 112 of the semiconductor module 100, the semiconductor module assembly 1000 may be more easily connected externally.

The first fins 204A and 204B may be formed on the second surfaces, which are outer surfaces, of the upper heat sink 200A and the lower heat sink 200B in order to dissipate heat generated by the semiconductor devices mounted on the semiconductor module 100. Spaces 500 may be provided between the clip 300, the upper heat sink 200A, and the lower heat sink 200B by the second fins 206A, 208A, 206B and 208B (the second fins 206A, 208A, 206B and 208B are not shown in FIG. 8 because of the cross sectional view depicted in FIG. 8 but can be seen in FIG. 2). The second fins 206A, 208A, 206B and 208B may be formed on the portions to which the clip 300 may be movably coupled and fixedly coupled.

The spaces 500 may be formed between the clip 300, the upper heat sink 200A, and the lower heat sink 200B. The spaces 500 may act as paths through which air can flow without being blocked when the semiconductor module assembly 1000 including the upper heat sink 200A and the lower heat sink 200B operates in an electronic system, thereby improving thermal convection efficiency. Accordingly, the clip 300 may allow the spaces 500 to be formed on the semiconductor module assembly 1000 such that air can freely flow through the second fins 206A, 208A, 206B, and 206B, each having a relatively low height, without interruption. Even though the size of the semiconductor module assembly 1000 including the upper heat sink 200A, the lower heat sink 200B may increase, and the number of clips 300 used may increase to 2, 4, and 6, thermal convection may be improved. Accordingly, the semiconductor module assembly 100 of FIG. 8 may improve the thermal reliability of the electronic system.

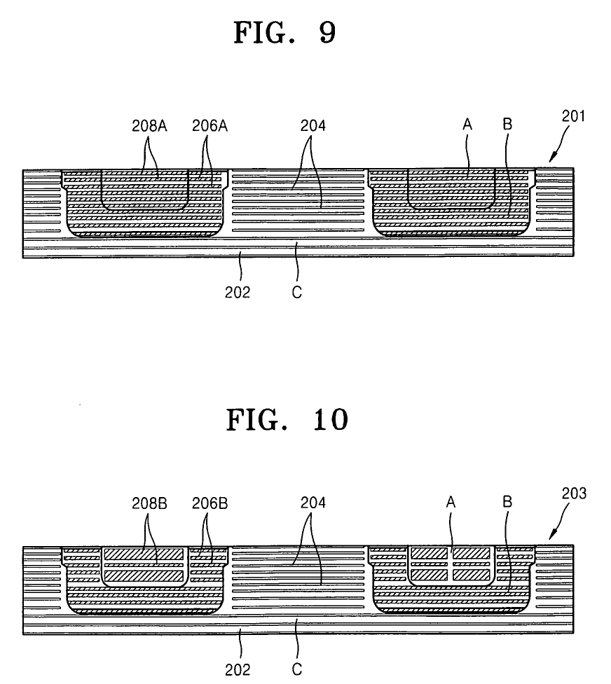

FIG. 9 is a plan view illustrating a modification of the heat sink 200 of FIG. 2. FIG. 10 is a plan view illustrating another modification of the heat sink 200 of FIG. 2. Referring to FIGS. 9 and 10, the semiconductor module assembly 1000 including the heat sink 200 of FIG. 2 may be modified in various ways. For example, the first fins 204 may be formed on a portion C of the heat sink base 202 to which no clip may be coupled and the second fins 206 and 208 may be formed on portions of the heat sink base 202 to which a clip may be coupled. The first fins 204 and the second fins 206 and 208 may have the same shape and pitch in example embodiments. First fins 204 may be formed on a portion C to which no clip may be coupled and second fins 206A and 208A may be formed on portions A and B to which a clip may be coupled may have different shapes and pitches as shown in FIG. 9. In example embodiments, the clip may be moved more easily in the portion A and may be fixed more easily to the portion B.

The first fins 204 and the second fins 206A and 208A may have different shapes and pitches in FIG. 9. Second fin 208B may have a first height formed on a portion A to which a clip may be movably coupled and second fin 206B may have a second height formed on a portion B to which the clip may be fixedly coupled. Second fins 208B and 206B may have different shapes and pitches as shown in FIG. 10.

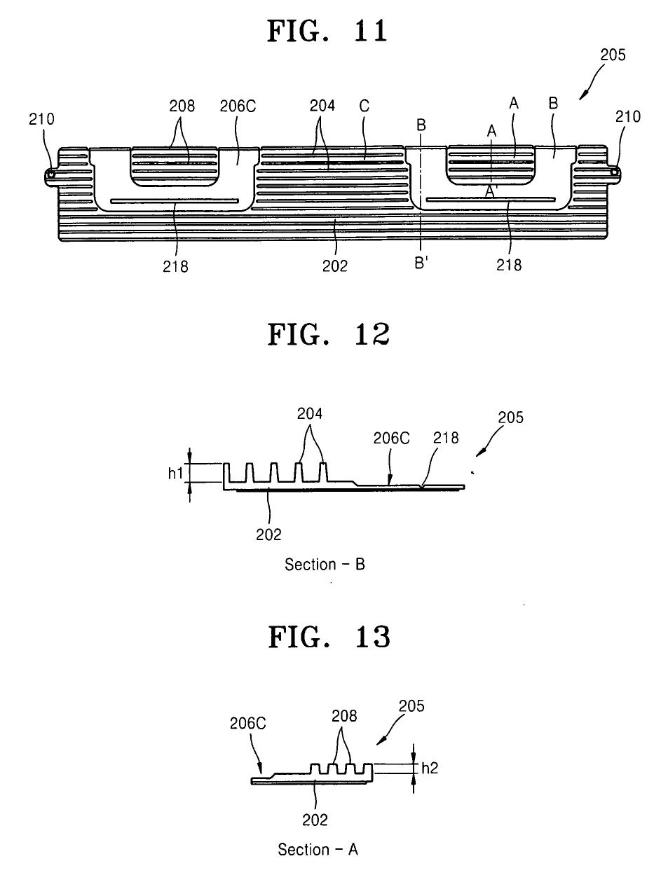

FIG. 11 is a plan view of a heat sink 205 according to example embodiments. Referring to FIG. 11, the heat sink 205 may include a similar structure to the heat sink 200 of FIG. 2 except that, among portions A and B to which a clip may be coupled, the portion A to which the clip may be movably coupled has second fins 208 and the portion B to which the clip may be fixedly coupled may include a recess area 206C. Because the recess area 206C may be lower in height than a heat sink base 202, if the clip is relatively thick and first fins 204 have a low height, a semiconductor module assembly including the heat sink 205 may be relatively thin. Because a groove 218 may be formed in the recess area 206C, even though a lower end of the clip does not have an outwardly bent shape but a linear shape, the clip may be removed from the heat sink 205 using the groove 218.

FIG. 12 is a cross-sectional view taken along line B-B′ of FIG. 11. FIG. 13 is a cross-sectional view taken along line A-A′ of FIG. 11. Referring to FIGS. 12 and 13, the first fins 204 may be formed on the portion C of the heat sink base 202 to which no clip may be coupled having a height h1 and the recess area 206C may be recessed from the heat sink base 202. Because the groove 218 may be formed in the recess area 206C, the clip may be more easily removed from the heat sink 205 using the groove 218.

Although fins may not be formed in the recess area 206C which corresponds to a portion B to which the clip may be fixedly coupled in FIGS. 12 and 13, second fins 206 that may have a second height (see FIG. 2) may be formed on the recess area 206C. Because second fins 208 may include a height h2, which may be formed on a portion A to which the clip may be movably coupled, thermal convection in the portion A may be improved.

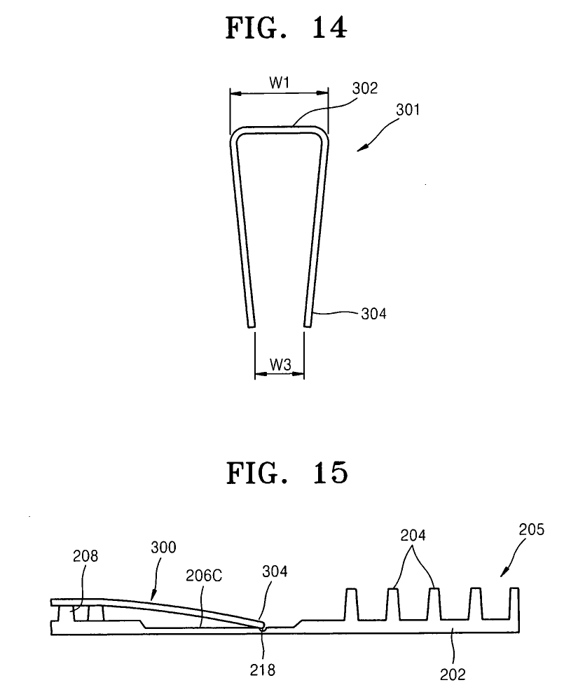

FIG. 14 is a side view of a clip 302 for securing the heat sink of FIG. 11 and a semiconductor module according to example embodiments. Referring to FIG. 14, although the end of the clip 300 may be bent outward in FIGS. 5 and 6, the clip 302 of FIG. 14 may have a U-shaped structure whose upper end may include a width W1 greater than a width W3 of a lower end 304 that may be linear and not bent outward. However, the lower end of the clip 302 may be bent outward as shown in FIG. 6.

FIG. 15 is a cross-sectional view illustrating the groove 218 that may be formed in the recess area 206C of the heat sink 205 of FIG. 11 according to example embodiments. Referring to FIG. 15, the recess region 206C of the heat sink 205 may include a height less than that of the heat sink base 202, and the groove 218 may be formed in a position of the recess area 306C where the lower end 304 of the clip 300 may be provided. Accordingly, the clip 300 coupled to the heat sink 205 may be more easily removed from the heat sink 205 using the groove 218.

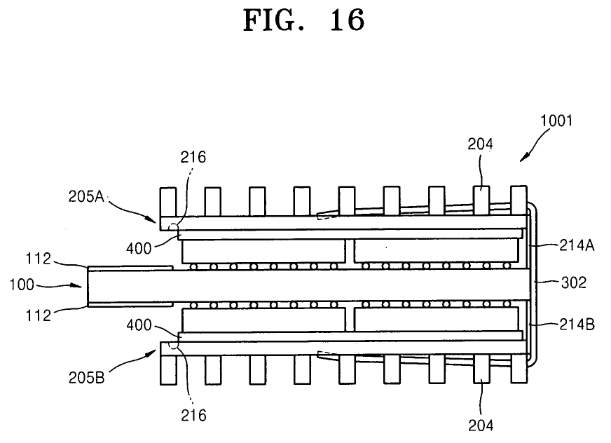

FIG. 16 is a cross-sectional view of a semiconductor module assembly including the heat sink 205 of FIG. 11 according to example embodiments. Referring to FIG. 16, a semiconductor module assembly 1001 including two heat sinks 205 (205A and 205B) of FIG. 11 may include a semiconductor module 100 which may include both surfaces on which semiconductor devices may be mounted. An upper heat sink 205A may be attached to the semiconductor devices mounted on one surface of the semiconductor module 100, and may include first fins 204 on a portion C of a heat sink base 202 to which no clip may be coupled, second fins may be on a portion A of the heat sink base 202 to which a clip 302 may be movably coupled, and a recess area 206C on a portion B of the heat sink base 202 to which the clip 302 may be fixedly coupled as shown in FIG. 11.

The semiconductor module assembly 1001 also may include a lower heat sink 205B attached to the semiconductor devices mounted on the other surface of the semiconductor module 100, and may further include first fins 204 which may be formed on a portion C of a heat sink base 202 to which a clip may not be coupled. Second fins 208 may be formed on a portion A of the heat sink base 202 to which the clip 302 may be movably coupled, and a recess area 206C (the heat sink base 202, second fins 208, and the recess area 206c are not shown in FIG. 16 because of the cross sectional view of FIG. 11 in FIG. 16) may be formed on a portion B of the heat sink base 202 to which the clip 302 may be fixedly coupled as shown in FIG. 11.

The semiconductor module assembly 1001 may also include the clip 302 securing the semiconductor module 100, the upper heat sink 205A, and the lower heat sink 205B. The clip 302 may have a linear shape whose lower end is not bent outward. TIMs 400 may be provided between first surfaces, which are inner surfaces, of the heat sink bases 202 of the upper heat sink 205A and the lower heat sink 205B, the semiconductor devices of the semiconductor module 100, and the U-shaped grooves 216 may be formed in the first surfaces of the heat sink bases 202 of the upper heat sink 205A and the lower heat sink 205B, as shown in FIG. 8.

Accordingly, thermal convection may be partially improved due to the second fins 208 on the portions of second surfaces, which are outer surfaces, of the heat sink bases 202 to which the clip 302 may be movably coupled, and the clip 302 may be partially inserted into the recess areas 206C formed in the heat sink base 202. Accordingly, when the first fins 204 formed on the second surfaces of the heat sink bases 202 have a relatively low height or the clip 302 may be relatively thick, the semiconductor module assembly 1001 may be relatively thin.

As described above, example embodiments have the following advantages. Because the fins may be formed on the portions of the outer surfaces of the heat sink bases to which the clip may be movably coupled and to which the clip may be fixedly coupled in order to secure the upper and lower heat sinks attached to the semiconductor module, thermal convection may be improved on the surfaces of the semiconductor module, thereby enhancing the thermal reliability of the semiconductor module assembly.

The clip may be smoothly moved by adjusting the shapes and pitches of the fins formed on the portions to which the clip may be movably coupled and fixedly coupled, thereby enhancing thermal dissipation effect on the surfaces of the semiconductor module.

Even though the size of the semiconductor module may increase and thus the number of clips used may increase, the clip may prevent or reduce a decrease of thermal dissipation on the surfaces of the semiconductor module.

While example embodiments have been particularly shown and described with reference to exemplary embodiments thereof, it will be understood by those of ordinary skill in the art that various changes in form and details may be made therein without departing from the spirit and scope of example embodiments as defined by the following claims.

What is claimed is:

1. A heat sink comprising:
a flat heat sink base having a first surface attached to semiconductor devices and a second surface externally exposed;
first fins on a portion of the second surface of the heat sink base to which no clip is coupled; and
second fins on portions of the second surface of the heat sink base to which a clip is coupled.

2. The heat sink of claim 1, wherein the portions of the second surface of the heat sink base to which the clip is coupled comprise:
a portion to which the clip is movably coupled and on which second fins having a first height are provided; and
a portion to which the clip is fixedly coupled and on which second fins having a second height are provided.

3. The heat sink of claim 2, wherein the first height of the second fins is greater than the second height of the second fins.

4. The heat sink of claim 1, wherein the first fins on the second surface of the heat sink base have a height greater than those of the second fins.

5. The heat sink of claim 1, wherein an end of the heat sink base has a fixing pin insertion hole.

6. The heat sink of claim 1, wherein the first surface of the heat sink base has a stepped structure conforming to the semiconductor devices having different heights which the first surface of the heat sink base contacts.

7. The heat sink of claim 1, wherein an edge of the first surface of the heat sink base has a U-shaped groove.

8. The heat sink of claim 1, wherein the first fins and the second fins have different shapes and pitches.

9. The heat sink of claim 2, wherein the second fins having the first height and the second fins having the second height have different shapes and pitches.

10. The heat sink of claim 1, wherein the heat sink base further comprises support bars that are connected to the flat heat sink base and are bent at about 90 degrees.

11. A semiconductor module assembly comprising:
a semiconductor module on both surfaces of which semiconductor devices are mounted; and
at least two heat sinks according to claim 1, wherein one heat sink is an upper heat sink attached to the semiconductor devices mounted on one surface of the semiconductor module, and the other heat sink is a lower heat sink attached to the semiconductor devices mounted on the other surface of the semiconductor module.

12. The semiconductor module assembly of claim 11, further comprising:
the clip, wherein the clip secures the semiconductor module, the upper heat sink, and the lower heat sink.

13. The semiconductor module assembly of claim 12, wherein the portions of the second surface of the heat sink base of each of the upper and lower heat sinks to which the clip is coupled comprise:
a portion to which the clip is movably coupled and on which second fins having a first height are provided; and
a portion to which the clip is fixedly coupled and on which second fins having a second height are provided.

14. The semiconductor module assembly of claim 12, wherein the first fins on the portion of the second surface of the heat sink base of each of the upper and lower heat sinks to which no clip is coupled has a height greater than those of the second fins on the portions of the second surface of the heat sink base of each of the upper and lower heat sinks to which the clip is coupled.

15. The semiconductor module assembly of claim 12, wherein the first surface opposite to the second surface of each of the upper and lower heat sinks has a stepped surface conforming to the semiconductor devices having different heights which are mounted on the semiconductor module and a U-shaped groove along an edge of the stepped surface.

16. The semiconductor module assembly of claim 12, wherein the upper and lower heat sinks further comprise support bars that are connected to the heat sink bases and are bent at about 90 degrees,
wherein the support bars of the upper and lower heat sinks alternately engage with each other.

17. The semiconductor module assembly of claim 16, wherein the clip has a U-shaped structure whose upper end is wider than a lower end that is bent outward, and secures the semiconductor module, the upper heat sink, and the lower heat sink in a direction in which the support bars of the upper and lower heat sinks engage with each other.

18. The semiconductor module assembly of claim 12, wherein thermal interface materials (TIMs) are provided between the semiconductor devices of the semiconductor module and the first surfaces of the upper and lower heat sinks.

19. The semiconductor module assembly of claim 13, wherein the portion to which the clip is fixedly coupled is in a recess area that is on a second portion of the surface of the heat sink base.

20. The semiconductor module assembly of claim 12, wherein the clip has a U-shaped structure whose upper end is wider than a lower end that is linear.

21. The semiconductor module assembly of claim 20, wherein a groove is provided in a position of the recess area of each of the upper and lower heat sinks where the lower end of the clip is provided.
